(19) United States
(12) Patent Application Publication
(10) Pub. No.: US 2015/0054517 A1
(43) Pub. Date: Feb. 26, 2015

(54) DIAGNOSIS APPARATUS AND DIAGNOSIS METHOD FOR RELAY CIRCUIT

(71) Applicants: FUJITSU LIMITED, Kawasaki-shi (JP); FUJITSU TEN LIMITED, Kobe-shi (JP); TRANSTRON INC, Yokohama-shi (JP)

(72) Inventors: Keiichi YONEZAKI, Kobe (JP); Shinji NAKAMURA, Kobe (JP); Masaki MIYAMOTO, Kobe (JP); Jun SASAKI, Yokohama (JP); Kazutoshi NISHIJIMA, Yokohama (JP); Yousuke OGURA, Yokohama (JP)

(73) Assignees: FUJITSU LIMITED, Kawasaki-shi (JP); FUJITSU TEN LIMITED, Kobe-shi (JP); TRANSTRON INC, Yokohama-shi (JP)

(21) Appl. No.: 14/448,171

(22) Filed: Jul. 31, 2014

(30) Foreign Application Priority Data
Aug. 26, 2013 (JP) 2013-174679

(51) Int. Cl. G01R 31/327

(52) U.S. Cl. CPC G01R 31/3274; G01R 31/3275
USPC 324/418

(57) ABSTRACT

An example of a relay circuit includes: a capacitor connecting both ends of a load circuit; first and second main relays disposed in power supply lines between a direct-current power supply and the load circuit; a series circuit configured by a first resistor and a precharge relay disposed in parallel with the first main relay; and a second resistor connecting both ends of the load circuit. A discharge process is performed in which both the first main relay and the precharge relay are turned on, the second main relay is turned off, and a reactive current is caused to flow through the load circuit. In this discharge process, an abnormality of the first resistor is detected based on a both-end voltage of the capacitor detected by a voltage sensor and a resistance value that is an equivalent representation of the discharge process.

### CROSS-REFERENCE TO RELATED APPLICATION

This application is based upon and claims the benefit of priority of the prior Japanese Patent Application No. 2013-174679, filed on Aug. 26, 2013, the entire contents of which are incorporated herein by reference.

### FIELD

The embodiments discussed herein are related to a diagnosis apparatus and a diagnosis method for a relay circuit.

### BACKGROUND

A DC power supply available to flow a large current with a voltage of 200 V or higher may be used for electric vehicles or hybrid vehicles, for example. Accordingly, for the purpose of security and the like, a relay contact may be provided in a power supply line so as to completely separate the DC power supply from a load circuit such as an inverter or a motor when the DC power supply is not in use.

However, the relay contact may be welded due to discharges occurred during on-off control of the relay contact. As examples of technologies for diagnosing such welding, technologies disclosed in Japanese Laid-open Patent Publication No. 2000-278802 and International Publication Pamphlet No. WO 2004/088696 are known.

Japanese Laid-open Patent Publication No. 2000-278802 discloses a system which determines a malfunction in a discharging system for discharging electric charge accumulated in a capacitor by using a motor coil. This determination system can determine whether discharge is performed normally, whether there is an abnormality of the motor coil, and whether there is an abnormality of a discharge resistor, based on a change (slope) of the both-end voltage of an inverter with respect to the time after start of the discharge.

Meanwhile, International Publication Pamphlet No. WO 2004/088696 discloses a method and an apparatus for detecting the welding of a relay contact. This detection method (or apparatus) performs sequence (turning on/off) control on first and second main relays and a precharge relay. The first and second main relays are provided in positive and negative power supply lines of a DC power supply. The precharge relay is provided in parallel with the contact of the first main relay and is configured by a resistor and a contact. In the sequence control, it is determined whether any one of the first and second main relays is welded by checking whether or not the both-end voltage of a load circuit decreases.

However, according to the technology disclosed in Japanese Laid-open Patent Publication No. 2000-278802, when relay welding occurs, there is no change in the both-end voltage of the inverter, and accordingly, the occurrence of the relay welding itself can be identified but a welding-occurred relay would not be identified.

In contrast, according to the technology disclosed in International Publication Pamphlet No. WO 2004/088696, it can be determined which one of the first and second main relays is welded. However, in a case where the resistance value of the load circuit is much higher than the resistance value of the resistor (precharge resistor) of the precharge relay, the both-end voltage of the load circuit decreases in low speed, and accordingly, quick or rapid diagnosis would not be available.

For example, in a case where the resistance value of the load circuit (discharge resistor) is 160 kΩ while the resistance value of the precharge resistor is 300Ω, it takes a time to perform discharge through the load circuit, and accordingly, the quick or rapid diagnosis would not be available. In other words, according to the technology disclosed in International Publication Pamphlet No. WO 2004/088696, the time required for the diagnosis depends on the ratio between the resistance values of the precharge resistor and the discharge resistor.

In addition, according to the technology disclosed in International Publication Pamphlet No. WO 2004/088696, it can be determined which main relay is welded, however, a detection of an abnormality of a circuit component (for example, an abnormality of the precharge resistor) is not available.

### SUMMARY

According to an aspect of the embodiment(s), there is provided a diagnosis apparatus for a relay circuit. The relay circuit includes: a load circuit supplied with a direct-current (DC) voltage from a direct-current (DC) power supply; a capacitor connected to both ends of the load circuit; a first main relay provided for a power supply line between a positive terminal of the DC power supply and one end of the load circuit; a second main relay provided for a power supply line between a negative terminal of the DC power supply and the other end of the load circuit; a series circuit of a first resistor and a precharge relay that are provided in parallel with the second main relay; and a second resistor connected to both ends of the load circuit. The diagnosis apparatus includes: a voltage sensor configured to detect a both-end voltage of the capacitor; a relay controller configured to performs an on-off control on each of the relays in accordance with a predetermined sequence; and a determiner configured to detect an abnormality of the first resistor based on the voltage detected by the voltage sensor and an equivalent resistance value representing a discharge process in a sequence including the discharge process, the discharge process being performed by the relay controller to turn on both of the first main relay and the precharge relay and turn off the second main relay to apply a reactive current with an amount indicated by a value stored in a memory to the load circuit.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating an example of the configuration of a vehicle according to a first embodiment focusing on a motor driving system;

FIG. 2 is a diagram illustrating an example of the state of Sequence #1 in the configuration illustrated in FIG. 1;

FIG. 3 is a diagram illustrating an example of the state of Sequence #2 in the configuration illustrated in FIG. 1;

FIG. 4 is a diagram illustrating an example of the state of Sequence #3 in the configuration illustrated in FIG. 1;

FIG. 5 is a graph illustrating an example of a change in a discharge resistance value with respect to a discharge current value;

FIG. 6 is a diagram illustrating an example of the state of Sequence #4 in the configuration illustrated in FIG. 1;

FIG. 7 is a diagram illustrating an example of the state of Sequence #5 in the configuration illustrated in FIG. 1;

FIG. 8 is a diagram illustrating an example of the state of Sequence #6 in the configuration illustrated in FIG. 1;

FIG. 9 is a diagram illustrating examples of a change in the both-end voltage (C voltage) of a capacitor C with respect to time, a change in the on-off state of each relay, and a change in a discharge current amount in Sequences #1 to #6;

FIG. 10 is a diagram illustrating examples of a change in the both-end voltage (C voltage) of the capacitor C with respect to time, a change in the on-off state of each relay, and a change in the discharge current amount in Sequences #1 to #6;

FIG. 11 is a diagram illustrating examples of a change in the both-end voltage (C voltage) of the capacitor C with respect to time, a change in the on-off state of each relay, and a change in the discharge current amount in a case where a precharge relay is welded before the start of Sequences #1 to #6;

FIG. 12 is a flowchart illustrating Sequences #1 to #5 according to the first embodiment;

FIG. 13 is a flowchart illustrating Sequences #5 and #6 according to the first embodiment;

FIG. 14 is a flowchart illustrating Sequences #1 to #5 according to a second embodiment;

FIG. 15 is a flowchart illustrating Sequences #5 and #6 according to the second embodiment;

FIG. 16 is a diagram illustrating examples of a change in the both-end voltage (C voltage) of a capacitor C with respect to time, a change in the on-off state of each relay, and a change in a discharge current amount in Sequences #1 to #6 according to the second embodiment;

FIG. 17 is a diagram illustrating examples of a change in the both-end voltage (C voltage) of the capacitor C with respect to time, a change in the on-off state of each relay, and a change in the discharge current amount in a case where a positive-side main relay is welded in the second embodiment;

FIG. 18 is a flowchart illustrating a third embodiment;

FIG. 19 is a flowchart illustrating Sequences #1 to #5 according to a fourth embodiment;

FIG. 20 is a flowchart illustrating Sequences #5 and #6 according to the fourth embodiment;

FIG. 21 is a diagram illustrating examples of a change in the both-end voltage (C voltage) of a capacitor C with respect to time, a change in the on-off state of each relay, and a change in a discharge current amount in Sequences #1 to #6 according to the fourth embodiment;

FIG. 22 is a flowchart illustrating Sequences #1 to #5 according to a fifth embodiment; and

FIG. 23 is a flowchart illustrating Sequences #5 and #6 according to the fifth embodiment.

### DESCRIPTION OF EMBODIMENTS

Hereinafter, exemplary embodiments will be described with reference to the appended drawings. Here, the following embodiments are merely exemplary, and are not intended to exclude applications of various modifications or techniques which are not described below. In the drawings used in the following embodiments, the same components are denoted by the same reference numerals unless otherwise set forth.

### First Embodiment

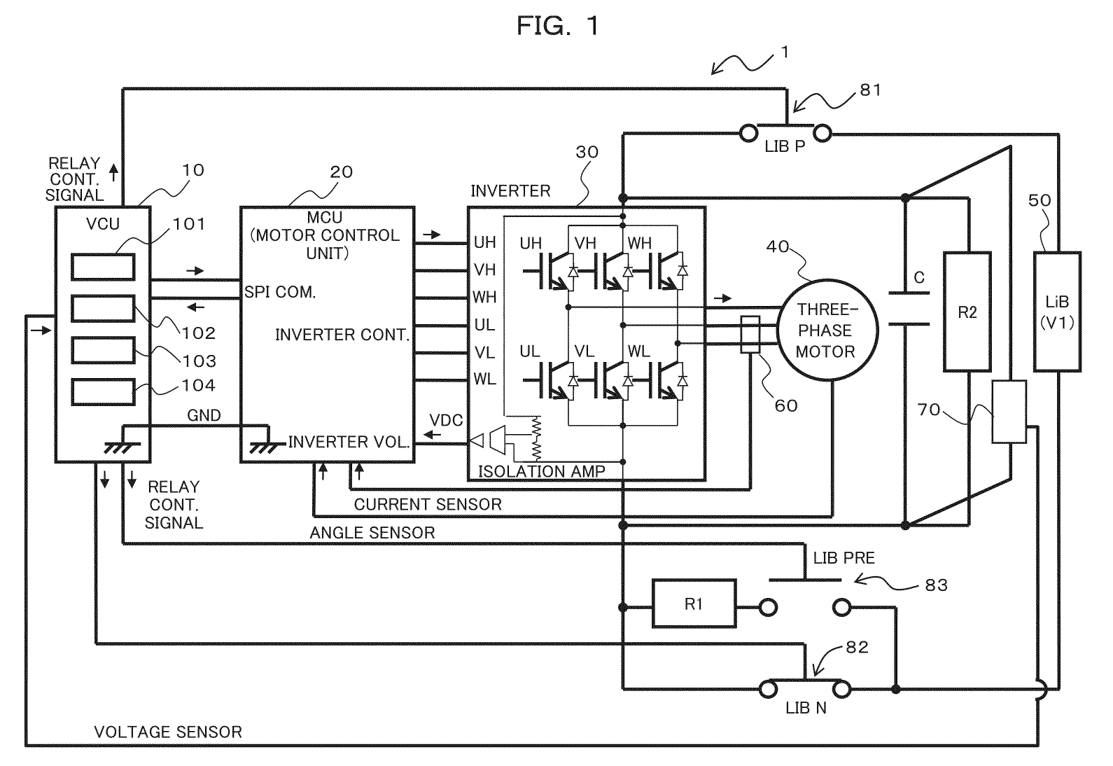

FIG. 1 is a block diagram illustrating an example of the configuration of a vehicle according to a first embodiment focusing on a motor driving system. For example, the motor drive system 1 illustrated in FIG. 1 is used in a next-generation vehicle such as an electric vehicle (EV) or a hybrid vehicle (HEV). The motor drive system 1, for example, includes a vehicle control unit (VCU) 10, a motor control unit (MCU) 20, an inverter 30, a three-phase motor 40, and a lithium ion battery (LiB) 50.

The VCU 10 controls the traveling of the vehicle by transmitting a drive control signal such as a torque instruction value to the MCU 20 based on an accelerator sensor signal and a brake sensor signal acquired by an accelerator sensor and a brake sensor not illustrated in the figure. For example, the VCU 10 performs an instruction for the calculation or regeneration of a drive torque based on the accelerator sensor signal, an instruction for the calculation of a regenerated energy amount based on the brake sensor signal, control of drivability, and the like.

The MCU 20 is communicably connected to the VCU 10 through a serial peripheral interface (SPI) or the like. The MCU 20 controls the inverter 30 based on a traveling control signal given from the VCU 10 through SPI communication, thereby drive power given to the three-phase motor 40 is controlled.

For example, the MCU 20 performs feedback control of the three-phase motor 40 based on a torque instruction value and sensor signals of an angle sensor (resolver) and a current sensor 60 provided in the three-phase motor 40 such that the torque of the three-phase motor 40 coincides with the torque instruction value given from the VCU 10.

The inverter 30 receives a power source voltage (battery voltage: V1) from the LiB 50, generates a drive voltage of the three-phase motor 40 in accordance with drive power control performed by the MCU 20, and supplies drive power to the three-phase motor 40 as the three-phase AC. For example, the inverter 30 is configured using an IGBT module in which a switching element such as an insulated gate bipolar transistor (IGBT) and a free wheel diode forms an anti-parallel connection.

As illustrated in FIG. 1, the inverter 30 includes, for example, three IGBT elements UH, VH, and WH forming upper arms of the U phase, the V phase, and the W phase and three IGBT elements UL, VL, and WL forming lower arms of the U phase, the V phase, and the W phase. The gate voltages of the six IGBT elements UH, VH, WH, UL, VL, and WL are individually controlled by the MCU 20, whereby the drive power of the three-phase AC given to the three-phase motor 40 is controlled.

In addition, the inverter 30 detects a battery voltage VDC received from the LiB 50 using an isolation amplifier and supplies the detected battery voltage VDC to the MCU 20 as an inverter voltage. The MCU 20 is operable to notify the VCU 10 of the inverter voltage, for example, through the SPI communication, and accordingly, the VCU 10, for example, is operable to detect (monitor) an abnormality of an inverter voltage.

A capacitor C and a resistor R2 are connected to both of positive and negative ends of the inverter 30 in parallel. The capacitor C is a smoothing capacitor and suppresses a variation of the input voltage input from the LiB 50 to the inverter 30. When both of a first main relay and a precharge relay are turned on, and a second main relay is turned off, a divided voltage ratio of the battery voltage V1 supplied from the LiB 50 is determined by the resistor R2 together with the resistor (precharge resistor) R1. This will be described later in detail.

The three-phase motor 40 is an example of a driving source of the vehicle and is provided with the resolver and the current sensor 60 described above. The inverter 30 and the three-phase motor 40 are examples of the load circuit.

The LiB 50 is an example of the DC power supply and, for example, applies a DC voltage of 200 V or higher (for example, 300 V or the like) to the inverter 30. A first main relay (LIB P) 81 is disposed in the power supply line between the positive terminal of the LiB 50 and one terminal of the inverter 30. Further, a second main relay (LIB N) 82 is disposed in the power supply line between the negative terminal of the LiB 50 and the other terminal of the inverter 30. When both of the main relays 81 and 82 are turned on, power is supplied from the LiB 50 to the inverter 30. On the other hand, when both of the main relays 81 and 82 are turned off, the LiB 50 is electrically disconnected from the inverter 30 and the three-phase motor 40.

Furthermore, a series circuit configured by a resistor (precharge resistor) R1 and a precharge relay (LIB PRE) 83 is connected to the second main relay 82 in parallel therewith. The precharge resistor R1 is an example of a first resistor and the aforementioned resistor R2 is an example of a second resistor. Upon controlling both of the main relays 81 and 82 turned on, the precharge relay 83 may be turned on. However, the precharge relay is turned on after the positive-side main relay 81 is turned on and before the negative-side main relay 82 is turned on. Thereby, a charge current charging the capacitor C flows through the resistor R1, and the capacitor C is gradually charged. Therefore, even when the negative-side main relay 82 is turned on, a large inrush current toward the capacitor C is not generated. Thus, it is possible to prevent one or both of the main relays 81 and 82 from being welded.

The LiB 50, the resistors R1 and R2, the capacitor C, and the relays 81 to 83 described above configure an example of a relay circuit.

The on-off control on each relay 81 to 83, for example, is performed in accordance with a control signal (relay control signal) provided from the VCU 10. In this embodiment, as will be described later, by performing an on-off control on each of the relays 81 to 83 in accordance with a predetermined switching sequence and monitoring a change in the both-end voltage V of the capacitor C in the switching sequence, it is possible to detect whether or not any one relay is welded. Further, by monitoring a change in the both-end voltage V, it is possible to detect an abnormality of the precharge resistor R1.

For this, a voltage sensor 70 that senses (detects) a voltage is connected to both ends of the capacitor C (resistor R2). A voltage detection result obtained by the voltage sensor 70, for example, is supplied to the VCU 10. The VCU 10 detects whether a relay is welded and whether there is an abnormality of the precharge resistor R1 based on the voltage detection result (in other words, a change in the both-end voltage of the capacitor C (the resistor R2)) during the aforementioned switching sequence.

For this, the VCU 10 includes, for example, a relay controller 101, a determiner 102, a memory 103, and a discharge controller 104. These units 101 to 104 configure an example of the diagnosis apparatus for a relay circuit together with the voltage sensor 70.

The relay controller 101 performs an on-off control on each of the relays 81 to 83 in accordance with a switching sequence represented in Table 1 set out below.

The amount of a reactive current to flow during discharging in the sequence may be stored in the memory 103. The memory 103 may be installed in the MCU 20. The relay controller 101 performs control so that a reactive current of an amount indicated by a value read from the memory 103 flows.

The amount of the reactive current stored in the memory 103 in advance, for example, may be determined based on values of the precharge resistor R1, the capacitor C, the LiB voltage, the determination time, and the discharge resistor R_{dis}. The amount of the reactive current may be stored in the memory 103 when the product is shipped.

In Embodiments 4 and 5 to be described later, the amount of the reactive current in Sequences #1 to #4 and Sequences #5 and #6 may be changed. In such a case, the amount of the reactive current stored in the memory 103 may be read before start of the discharge in the sequence.

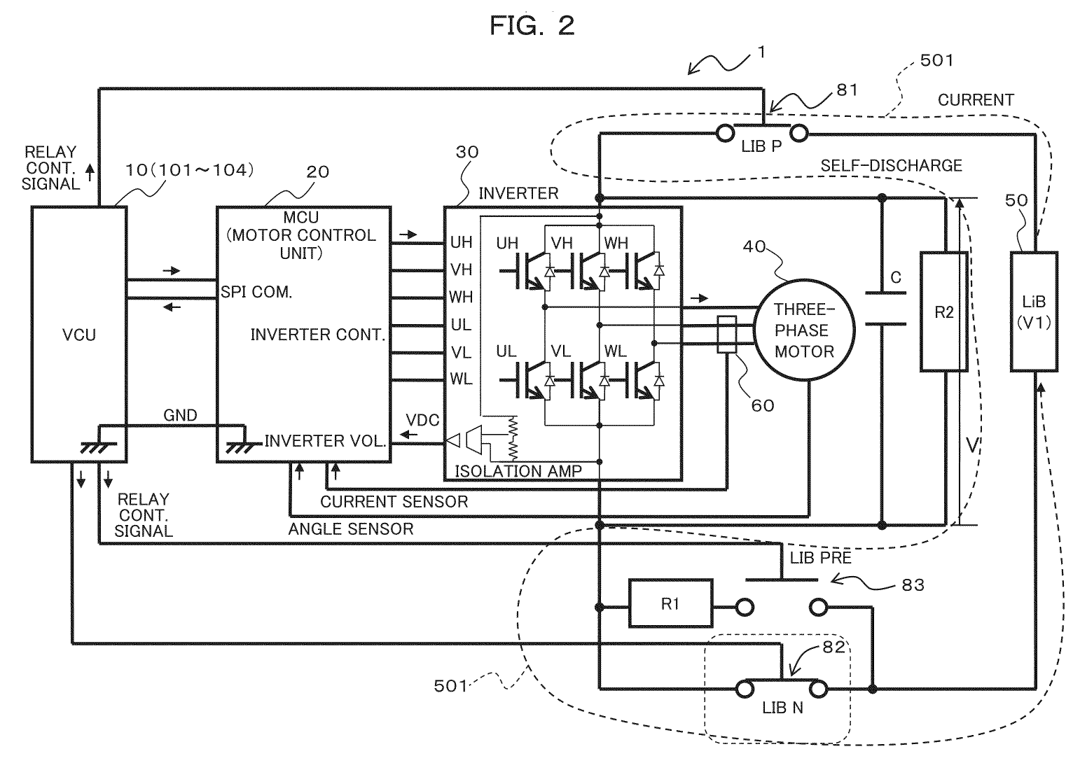

FIGS. 2 to 4 and 6 to 8 illustrate connection states of the relays 81 to 83 and current paths corresponding to Sequences #1 to #6. In FIGS. 2 to 4 and 6 to 8, the voltage sensor 70 is not illustrated.

TABLE 1
Switching Sequence

| Sequence No. | LIB PRE | LIB P | LIB N | Discharge |
|---|---|---|---|---|
| (Before Sequence) | OFF | ON | ON | No |
| 1 | OFF | ON | ON | No |
| 2 | OFF | ON | OFF | Yes |
| 3 | ON | ON | OFF | Yes |
| 4 | ON | OFF | OFF | Yes |
| 5 | ON | ON | OFF | Yes |
| 6 | OFF | ON | OFF | Yes |

In other words, before start of the sequence (before the inrush) and in Sequence #1, as illustrated in FIG. 2, the relay controller 101 controls both of the main relays 81 and 82 turned on and controls the precharge relay 83 turned off. In this case, the battery voltage is applied to both ends of the capacitor C (the resistor R2) from the LiB 50 (in other words, a voltage V detected by the voltage sensor 70 is V1), and self-discharge occurs in a path illustrated by a dotted-line arrow 501. In other words, a current flows in a path 501 starting from the LiB 50, passing through the positive-side main relay 81, the resistor R2, and the negative-side main relay 82, and returning to the LiB 50.

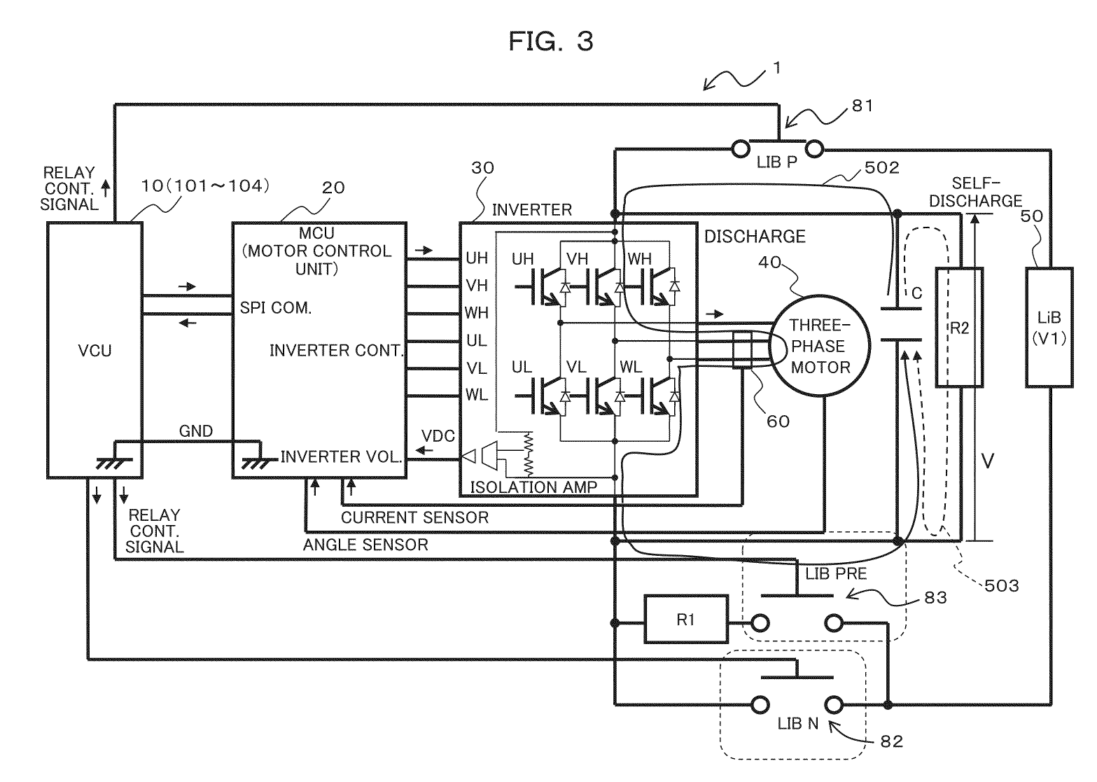

Thereafter, in Sequence #2, the relay controller 101, as illustrated in FIG. 3, controls the negative-side main relay 82 turned off. Further, the discharge controller 104 gives a discharge start instruction to the MCU 20. Thereby, the MCU 20 controls the IGBT element such that a reactive current flows into a d-axis of the three-phase motor 40 through the inverter 30.

In that case, a current flows in a path denoted by a solid-line arrow 502 in FIG. 3 (discharge). In other words, electric charge accumulated in the capacitor C flows from the positive side of the capacitor C to the d-axis of the three-phase motor 40 through the IGBT element configuring the upper arm of the inverter 30 (reactive current) and flows to the negative side of the capacitor C through the IGBT element configuring the lower arm of the inverter 30. Also, a part of the electric charge accumulated in the capacitor C flows to the resistor R2 in a path denoted by a dotted-line arrow 503 (self-discharge). The both-end voltage (in other words, a voltage detected by the voltage sensor 70) V of the capacitor (the resistor R2) at this time is decreased toward V=0.

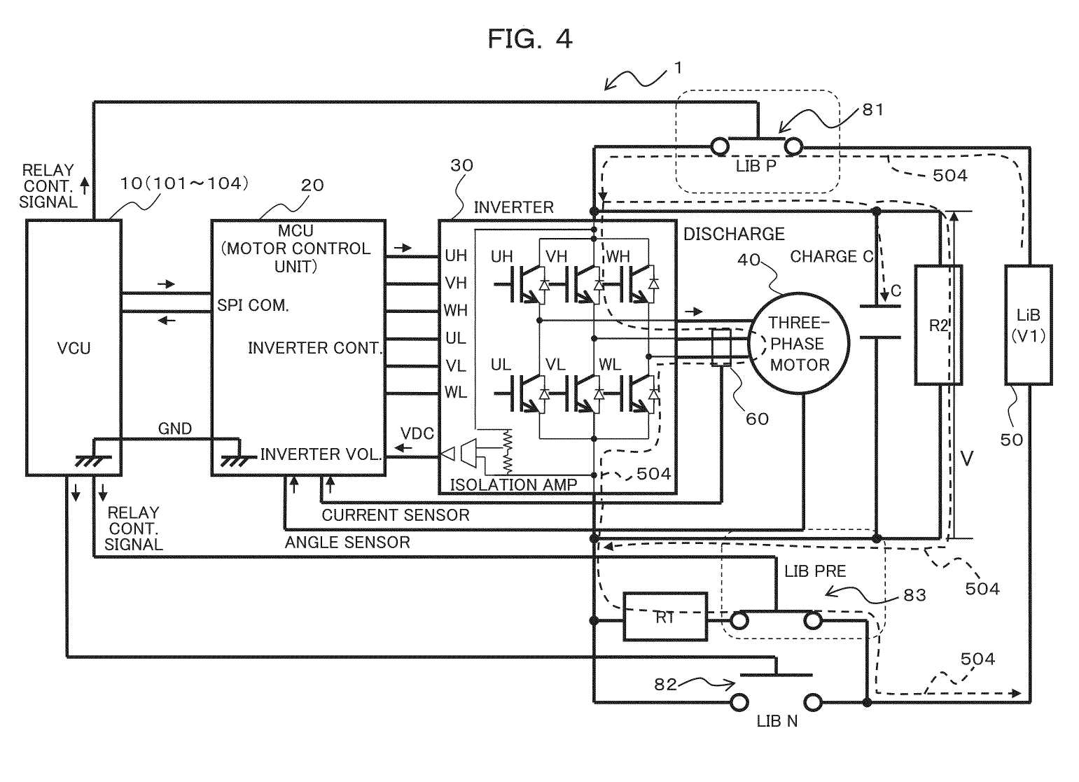

Thereafter, in Sequence #3, the relay controller 101, as illustrated in FIG. 4, controls the precharge relay 83 turned on. In that case, a current flows in a path illustrated by a dotted-line arrow 504 in FIG. 4. In other words, a current (discharge current) flows from the positive side of the LiB 50 to the negative side of the LiB 50 through the main relay 81, the inverter 30, the three-phase motor 40 (d axis), the precharge resistor R1, and the precharge relay 83. Further, a current flows from the positive side of the LiB 50 to the negative side of the LiB 50 through the main relay 81, the resistor R2, the precharge resistor R1, and the precharge relay 83. At this time, electric charge is accumulated (charged) in the capacitor C. In conclusion, the current flows to the d-axis of the three-phase motor 40 through the inverter 30, and the capacitor C is charged. The both-end voltage (in other words, a voltage detected by the voltage sensor 70) V of the capacitor C (the resistor R2) at this time is represented in the following Equation (1).

V=V1×{(R_{dis}·R2)/(R_{dis}+R2)}/{R1+(R_{dis}·R2)/(R_{dis}+R2)} (1)

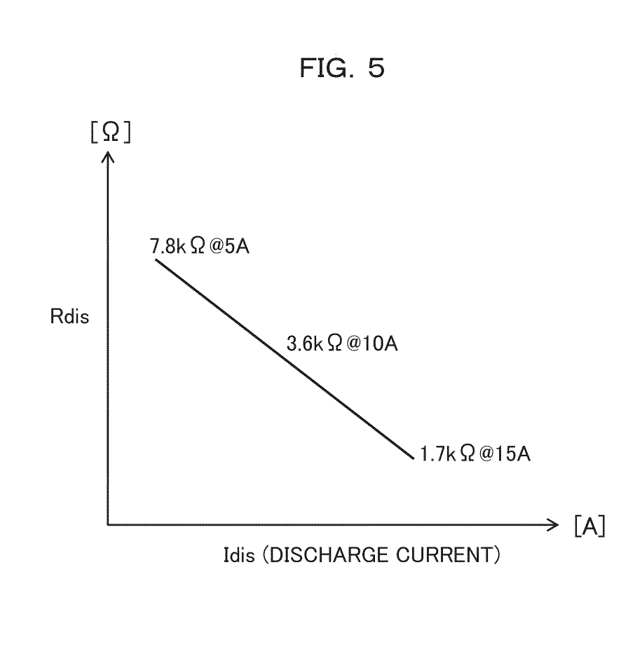

Here, R1 and R2 respectively represent resistance values of the resistors R1 and R2. For example, R1 is 300Ω and R2 is 180 kΩ. R_{dis} represents a resistance value in a case where the discharge is simulated as a resistor. For example, R_{dis} can be represented as a variable resistance value which changes in the range of about 1 kΩ. to 8 kΩ in a case where the discharge current I_{dis} changes in the range of 5 to 15 A (ampere), as illustrated in FIG. 5. The reason for the decrease in the both-end voltage of the capacitor C due to discharge (in other words, a decrease in the energy collected in the capacitor C) is that energy is consumed as heat in accordance with heat dissipation of the coil of the three-phase motor 40 in a coil resistor due to conduction and heat dissipation due to conduction of the IGBT and the diode and switching. The effect of the consumption of energy as such heat is equivalently simulated as discharge according to the resistor R_{dis}. Further, since the amount of consumption as heat is proportional to the amount of the discharge current, R_{dis} can be considered as a variable resistance value which is monotonously decreased in accordance with an increase in the discharge current (the amount of heat dissipation increases as the resistance value decreases).

Accordingly, in Sequence #3, the both-end voltage V of the capacitor C (the resistor R2) increases toward a value, which is represented in the above-described Equation (1), acquired by dividing the battery voltage V1 by the precharge resistance value R1 and the discharge resistance value R_{dis}.

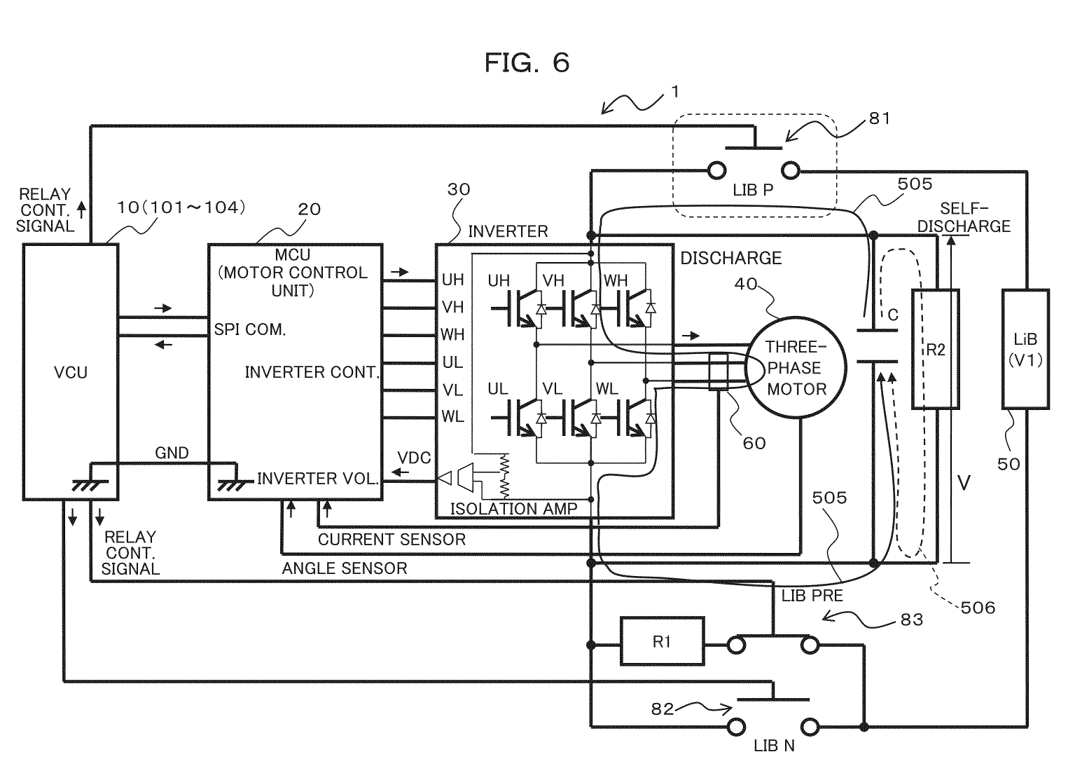

Next, in Sequence #4, the relay controller 101, as illustrated in FIG. 6, controls the positive-side main relay 81 turned off. In that case, a current flows in a path represented by a solid-line arrow 505 in FIG. 6 (discharge). In other words, electric charge accumulated in the capacitor C flows from the positive side of the capacitor C to the d-axis of the three-phase motor 40 through the IGBT element configuring the upper arm of the inverter 30 (reactive current) and flows to the negative side of the capacitor C through the IGBT element configuring the lower arm of the inverter 30. A part of the electric charge accumulated in the capacitor C also flows to the resistor R2 in a path denoted by a dotted-line arrow 506 (self-discharge). The both-end voltage (in other words, a voltage detected by the voltage sensor 70) V of the capacitor (the resistor R2) at this time is decreased toward V=0.

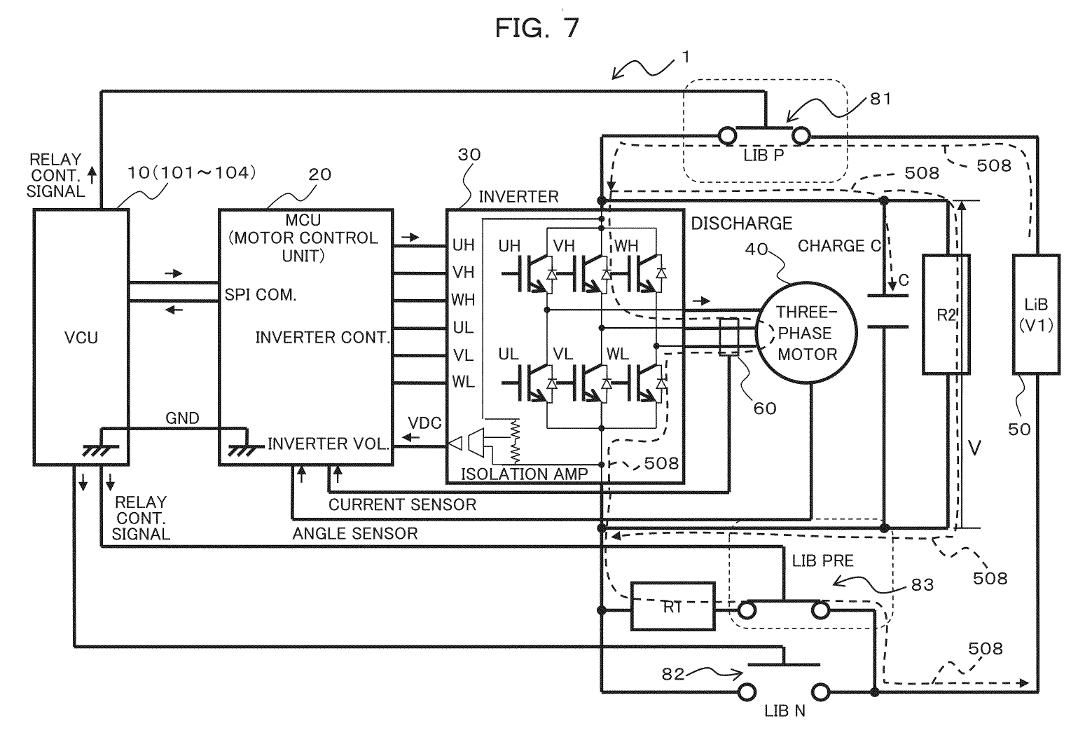

Thereafter, in Sequence #5, the relay controller 101, as illustrated in FIG. 7, controls the positive-side main relay 81 turned on. In that case, similar to the case of Sequence #3, a current flows in a path illustrated by a dotted-line arrow 508 in FIG. 7. In other words, the current flows to the d-axis of the three-phase motor 40 through the inverter 30, and the capacitor C is charged. The both-end voltage (in other words, a voltage detected by the voltage sensor 70) V of the capacitor C (the resistor R2) at this time is represented in Equation (1) described above.

Accordingly, in Sequence #5, the both-end voltage V of the capacitor C (the resistor R2) increases toward a value, which is represented in the above-described Equation (1), acquired by dividing the battery voltage V1 by the precharge resistance value R1 and the discharge resistance value R_{dis}.

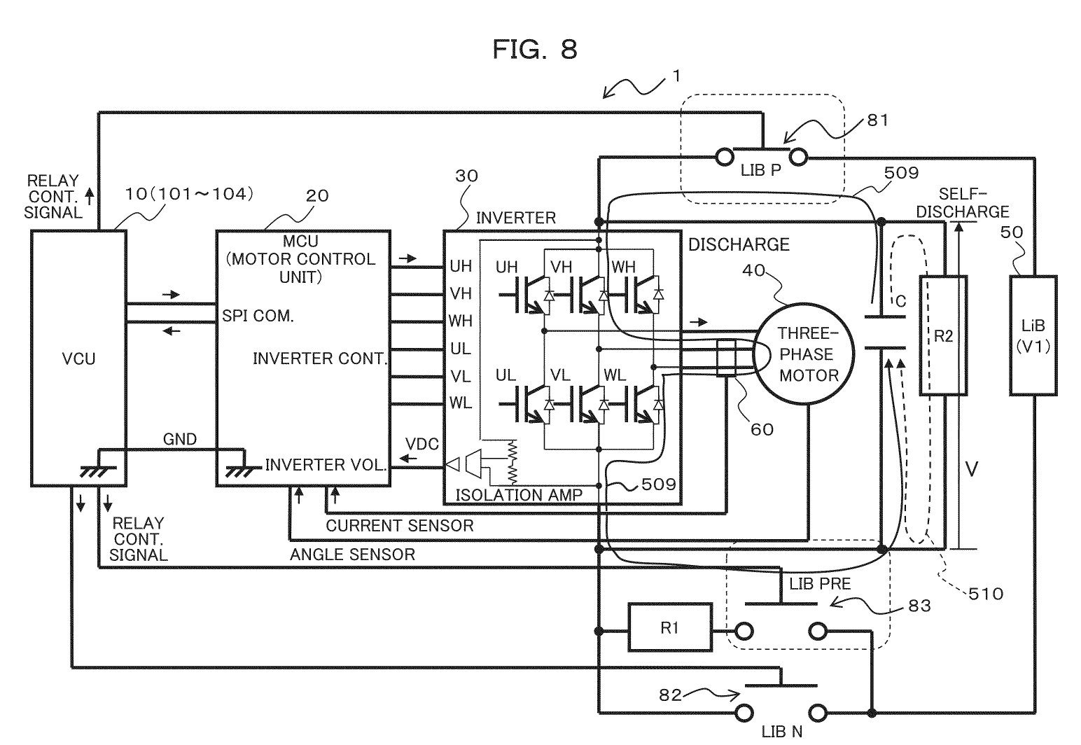

Next, in Sequence #6, the relay controller 101, as illustrated in FIG. 8, controls the precharge relay 83 turned off. In that case, similar to Sequence #2, a current flows in a path represented by a solid-line arrow 509 in FIG. 8 (discharge). In other words, electric charge accumulated in the capacitor C flows from the positive side of the capacitor C to the d-axis of the three-phase motor 40 through the IGBT element configuring the upper arm of the inverter 30 (reactive current) and flows to the negative side of the capacitor C through the IGBT element configuring the lower arm of the inverter 30. A part of the electric charge accumulated in the capacitor C also flows to the resistor R2 in a path denoted by a dotted-line arrow 510 (self-discharge). The both-end voltage (in other words, a voltage detected by the voltage sensor 70) V of the capacitor (the resistor R2) at this time is decreased toward V=0.

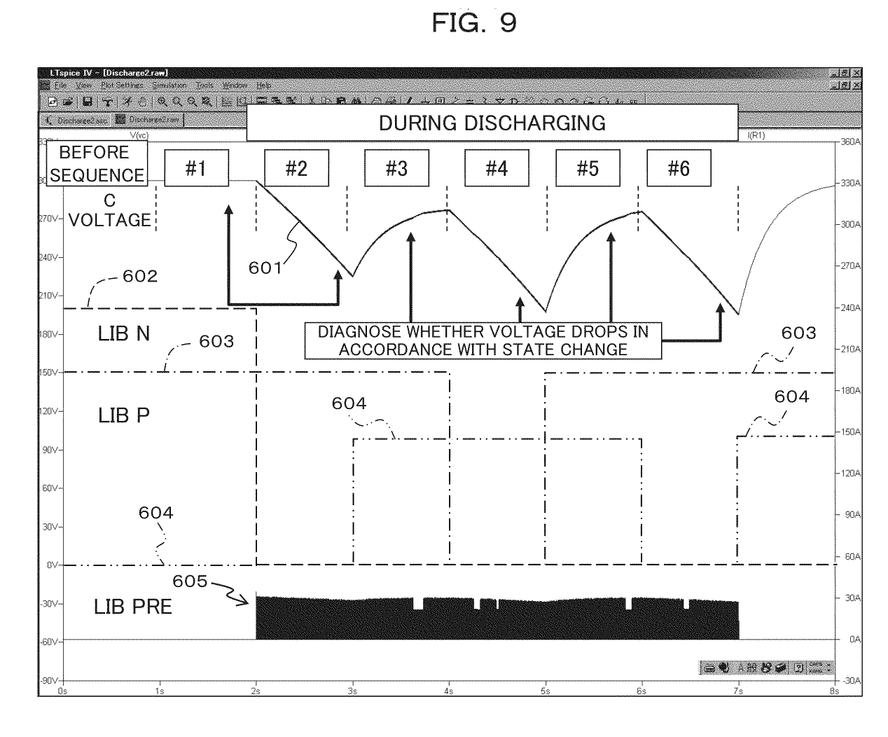

FIG. 9 illustrates examples of a change in the both-end voltage (C voltage) of the capacitor C with respect to time, a change in the on-off state of each of the relays 81 to 83, and a change in the discharge current amount in Sequences #1 to #6.

In FIGS. 9, #1 to #6 represent periods corresponding to Sequences #1 to #6, respectively. Further, a solid line 601 represents a change in the C voltage, a dotted line 602 represents a change in the on-off state of the negative-side main relay 82, and a dashed line 603 represents a change in the on-off state of the positive-side main relay 81. Furthermore, a two-dot chain line 604 represents a change in the on-off state of the precharge relay 83, and reference numeral 605 represents a change in the amount of the discharge current during the discharge period (a period corresponding to Sequences #2 to #6).

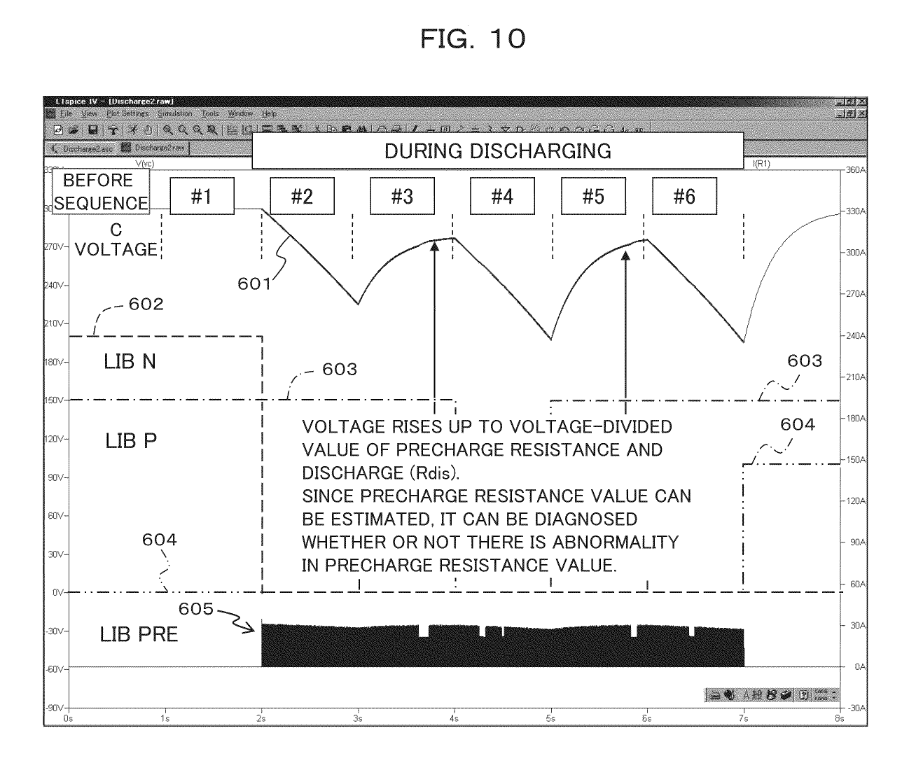

The VCU 10 is available to detect (diagnose) an abnormality of the battery voltage and whether any one of the relays 81 to 83 is welded by comparing the C voltage with a predetermined voltage threshold during the period corresponding to each of Sequences #1 to #6 by using the determiner 102. Further, as illustrated in FIG. 10, during the period corresponding to each of Sequences #3 to #5, the VCU 10 is also available to diagnose whether there is no abnormality of the precharge resistor R1 by comparing the C voltage with the predetermined voltage threshold by using the determiner 102.

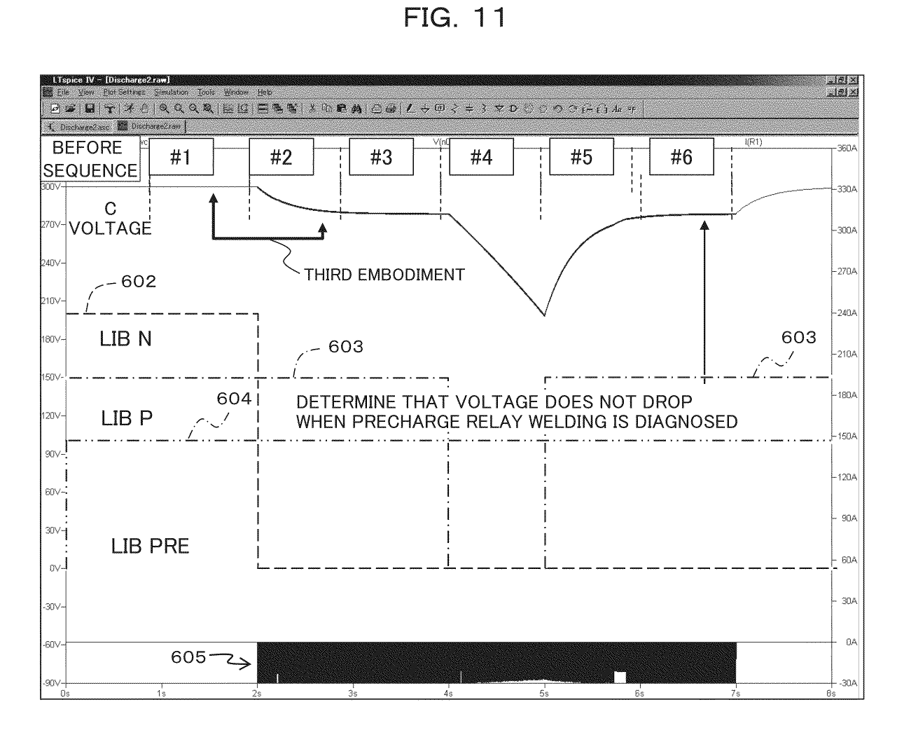

A case in which the precharge relay 83 has already been welded before the start of Sequences #1 to #6 may also be considered. In such a case, as illustrated in FIG. 11, the VCU 10 is available to diagnose whether or not the precharge relay 83 is welded by comparing the C voltage with a predetermined voltage threshold during the period corresponding to Sequence #6 by using the determiner 102. More specifically, it can be determined that the precharge relay 83 is welded in a case where the C voltage is not below the predetermined voltage threshold.

However, when the precharge relay 83 is welded, a voltage drop during the period corresponding to Sequence #2 is slow. Accordingly, by comparing a voltage drop value of the C voltage after the elapse of a predetermined time with a threshold, a welding diagnosis is available during the period corresponding to Sequence #2. This aspect will be described later in a third embodiment.

Each of the thresholds described above may be stored in, for example, the memory 103 and may be read by the determiner 102 appropriately.

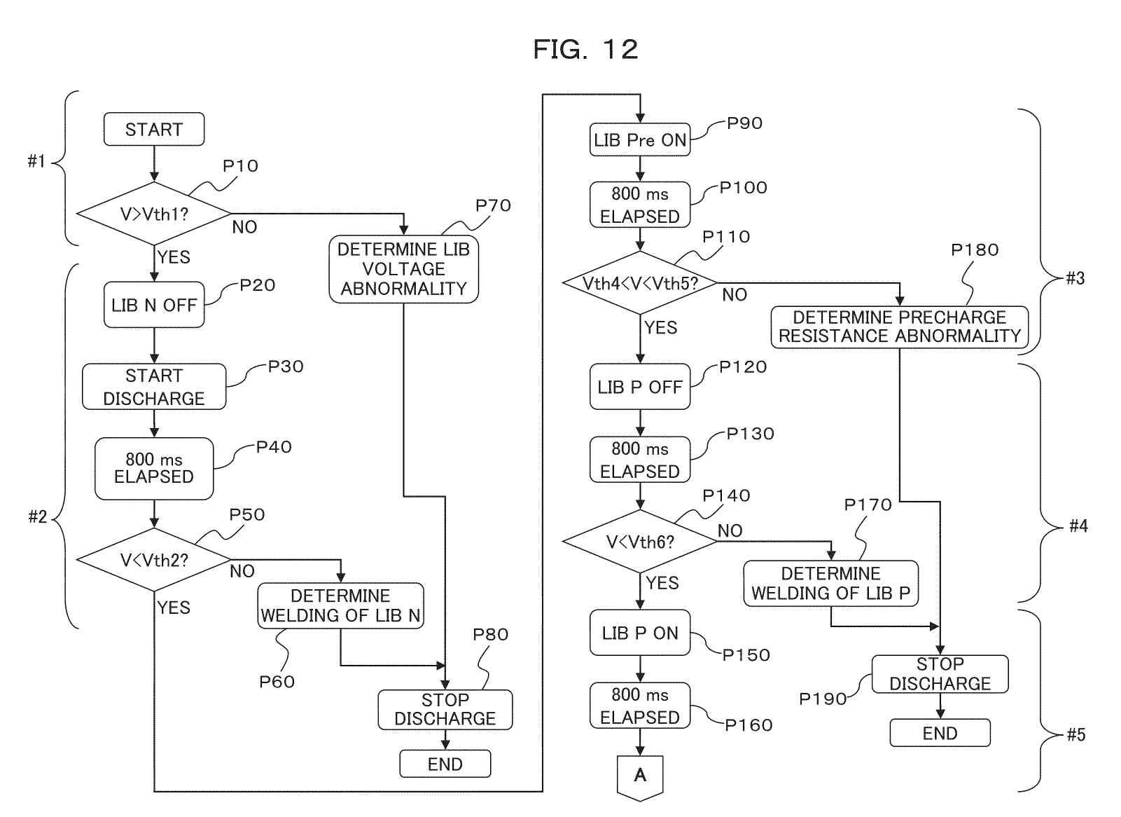

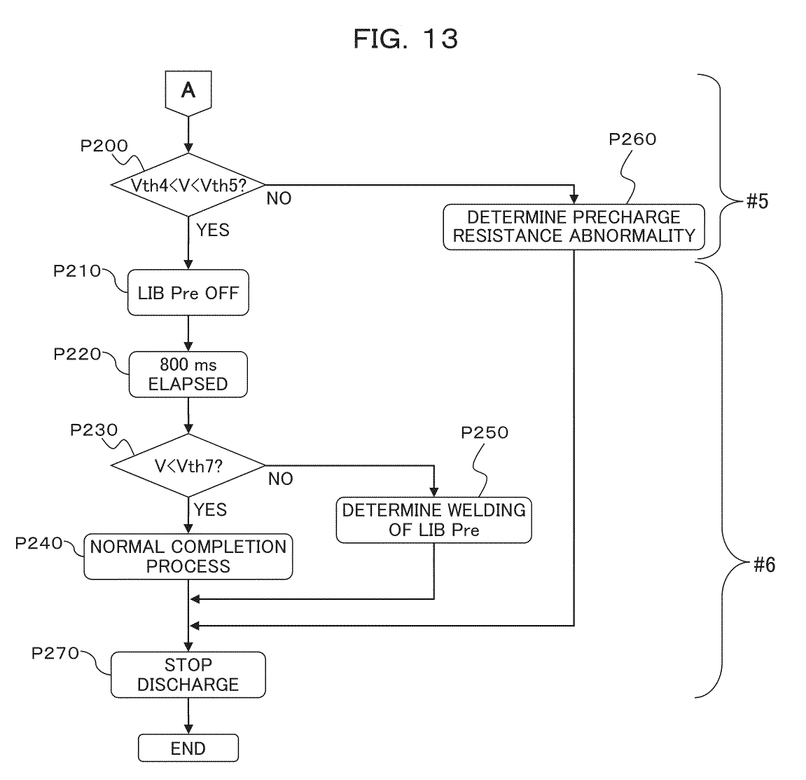

Hereinafter, a specific example of the above-described diagnosis will be described with reference to a flowchart illustrated in FIGS. 12 and 13. In FIGS. 12 and 13, #1 to #6 represent periods corresponding to Sequences #1 to #6, respectively.

First, as illustrated in FIG. 12, during the period corresponding to Sequence #1, the VCU 10 determines whether “V>Vth1” is satisfied by comparing the C voltage V detected by the voltage sensor 70 with a voltage threshold Vth1 using the determiner 102 (Process P10). For example, when the battery voltage V1 of the LiB 50 is 300 V, the voltage threshold Vth1 may be set to 290 V.

As a result, in a case where “V>Vth1” is not satisfied (“No” in Process P10), the determiner 102 determines that there is an abnormality of the battery voltage of the LiB 50 (Process P70). In this case, the VCU 10 (the relay controller 101) ends the process without performing subsequent Sequences #2 to #6 (discharge stop: Process P80).

On the other hand, in a case where V>Vth1 is satisfied (“Yes” in Process P10), the VCU 10 controls the negative-side main relay 82 turned off using the relay controller 101 (Process P20), and discharge is started by the discharge controller 104 (Process P30).

Thereafter, when a predetermined time (for example, 800 ms) elapses (Process P40), the VCU 10 determines whether V<Vth2 is satisfied by comparing the C voltage V detected by the voltage sensor 70 with a predetermined voltage threshold Vth2 (<Vth1) using the determiner 102 (Process P50). For example, in a case where the battery voltage V1 is 300 V, the voltage threshold Vth2 may be set to 250 V. Here, the predetermined time may be set in comprehensive consideration of the capacitance of the capacitor C, the discharge resistance value R_{dis}, a steady-state voltage value, switching control of the IGBT, the determination time, and the like (hereinafter, this similarly applies).

As a result, in a case where “V<Vth2” is not satisfied (in a case where the C voltage V is not below the voltage threshold Vth2: “No” in Process P50), the determiner 102 determines that the negative-side main relay 82 is welded (process P60). In such a case, the VCU 10 (the relay controller 101) stops discharge using the discharge controller 104 without performing subsequent Sequences #3 to #6 (Process P80) and ends the process.

On the other hand, in a case where “V<Vth2” is satisfied (“Yes” in Process P50), the VCU 10 controls the precharge relay 83 turned on using the relay controller 101 (Process P90). Thereafter, when a predetermined time (for example, 800 ms) elapses (Process P100), the VCU 10 determines whether “Vth4<V<Vth5” is satisfied by comparing the C voltage V with predetermined voltage thresholds Vth4 and Vth5 by using the determiner 102 (Process P110). Here, for example, the voltage threshold Vth4 satisfies Vth2<Vth4<Vth1, and the voltage threshold Vth5 satisfies Vth4<Vth5<Vth1. For example, in a case where the battery voltage V1 is 300 V, the voltage thresholds Vth4 and Vth5 may be set to 265 V and 285 V, respectively.

As a result, in a case where “Vth4<V<Vth5” is not satisfied (“No” in Process P110), the determiner 102 determines that there is an abnormality of the precharge resistor R1 (Process P180). In such a case, the VCU 10 (the relay controller 101) stops discharge by using the discharge controller 104 without performing subsequent Sequences #4 to #6 (Process P190) and ends the process.

On the other hand, in a case where “Vth4<V<Vth5” is satisfied (“Yes” in Process P110), the VCU 10 controls the positive-side main relay 81 turned off by using the relay controller 101 (Process P120). Thereafter, when a predetermined time (for example, 800 ms) elapses (Process P130), the VCU 10 determines whether “V<Vth6” is satisfied by comparing the C voltage V with a predetermined voltage threshold Vth6 by using the determiner 102 (Process P140). Here, for example, the voltage threshold Vth6 satisfies Vth6<Vth2. For example, in a case where the battery voltage V1 is 300 V, the voltage threshold Vth6 may be set to 230 V.

As a result, in a case where “V<Vth6” is not satisfied (“No” in Process P140), the determiner 102 determines that the positive-side main relay 81 is welded (process P170). In such a case, the VCU 10 (the relay controller 101) stops discharge by using the discharge controller 104 without performing subsequent Sequences #5 and #6 (Process P190) and ends the process.

On the other hand, in a case where “V<Vth6” is satisfied (“Yes” in Process P140), the VCU 10 controls the positive-side main relay 81 turned on by using the relay controller 101 (Process P150). Thereafter, when a predetermined time (for example, 800 ms) elapses (Process P160), as illustrated in FIG. 13, again, the determiner 102 determines whether “Vth4<V<Vth5” is satisfied by comparing the C voltage V with the predetermined voltage thresholds Vth4 and Vth5 (Process P200).

As a result, in a case where “Vth4<V<Vth5” is not satisfied (“No” in Process P200), the determiner 102 determines that there is an abnormality of the precharge resistor R1 (Process P260). In such a case, the VCU 10 (the relay controller 101) stops discharge by using the discharge controller 104 without performing the subsequent Sequence #6 (Process P270) and ends the process.

On the other hand, in a case where “Vth4<V<Vth5” is satisfied (“Yes” in Process P200), the VCU 10 controls the precharge relay 83 turned off by using the relay controller 101 (Process P210). Thereafter, when a predetermined time (for example, 800 ms) elapses (Process P220), the VCU 10 determines whether “V<Vth7” is satisfied by comparing the C voltage V with a predetermined voltage threshold Vth7 by using the determiner 102 (Process P230). Here, for example, the voltage threshold Vth7 satisfies Vth7<Vth2. For example, in a case where the battery voltage V1 is 300 V, the voltage threshold Vth7 may be set to 230 V. In other words, the voltage threshold Vth7 may be set to the same value as that of the voltage threshold Vth6 (=230 V).

As a result, in a case where “V<Vth7” is not satisfied (“No” in Process P230), the determiner 102 determines that the precharge relay 83 is welded (process P250). In such a case, the VCU 10 stops discharge by using the discharge controller 104 (Process P270) and ends the process.

On the other hand, in a case where “V<Vth7” is satisfied (“Yes” in Process P230), a normal end process is performed (Process P240). For example, the discharge controller 104 stops the discharge (Process P270), and the process ends.

As described above, according to the aforementioned embodiment, the discharge process is controlled in which a reactive current of a reactive current amount corresponding to the value stored in the memory 103 is caused to flow in the load circuit. Accordingly, speedy discharge can be performed, whereby a quick or rapid diagnosis can be achieved. Further, in the sequence performing the discharge process, an abnormality of the precharge resistor R1 can be detected based on the both-end voltage of the capacitor C, which is detected by the voltage sensor 70, and the resistance value R_{dis} that is an equivalent representation of the discharge process. Accordingly, the equivalent resistance value R_{dis} can be freely set without depending on the resistance value of the precharge resistor R1 and the like.

In the first embodiment described above, the switching control of the relays 81 to 83 is performed in order of Sequences #1 to #6, however; the order of the sequences may be changed. For example, a set of Sequences #3 and #4 and a set of Sequences #5 and #6 may be interchanged in the execution order. Further, in a case where the precharge relay 83 is turned on in a stage before the start of the sequences, a set of Sequences #1 and #2 and a set of Sequences #3 and #4 (or a set of Sequences #5 and #6) may be interchanged in the execution order.

### Second Embodiment

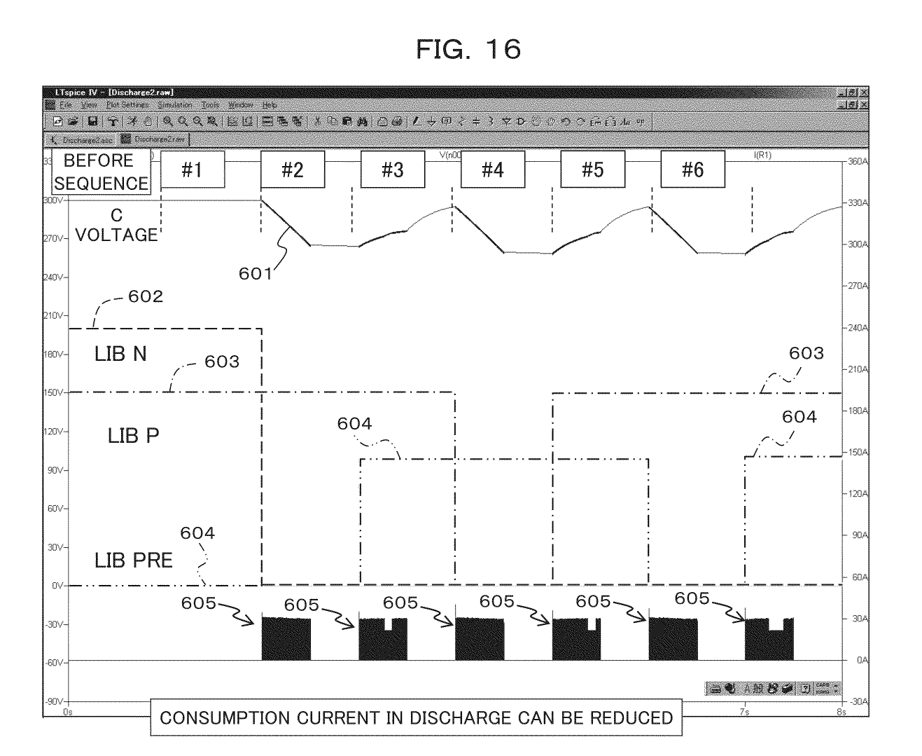

In the first embodiment described above, in the case of normal end, for example, as illustrated in FIG. 10, while discharge is continuously performed during the period corresponding to Sequences #2 to #6, for example. However, as denoted by reference numeral 605 in FIG. 16, inverter control may be performed such that discharge is intermittently performed by the discharge controller 104.

In such a case, the discharge controller 104 serves as an example of a discharge period controller that controls a period during which electric charge accumulated in the capacitor C or the electric charge supplied from the LiB 50 is discharged through the inverter 30 and the three-phase motor 40 for each sequence.

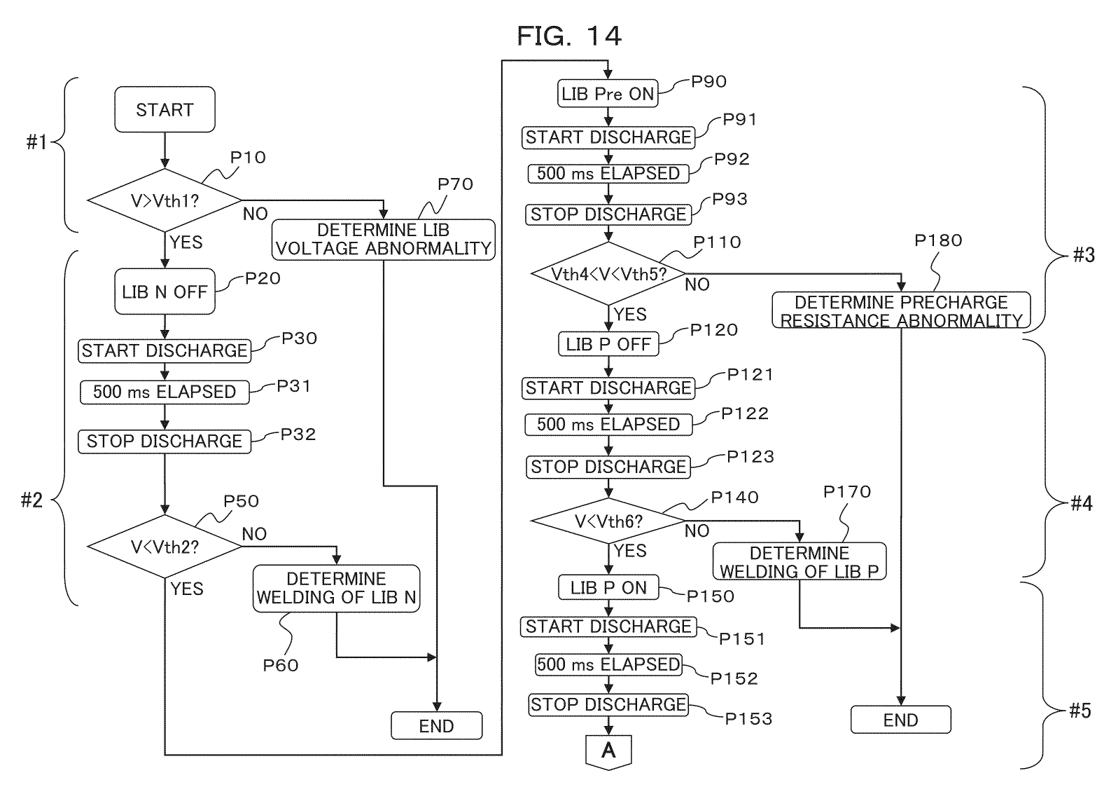

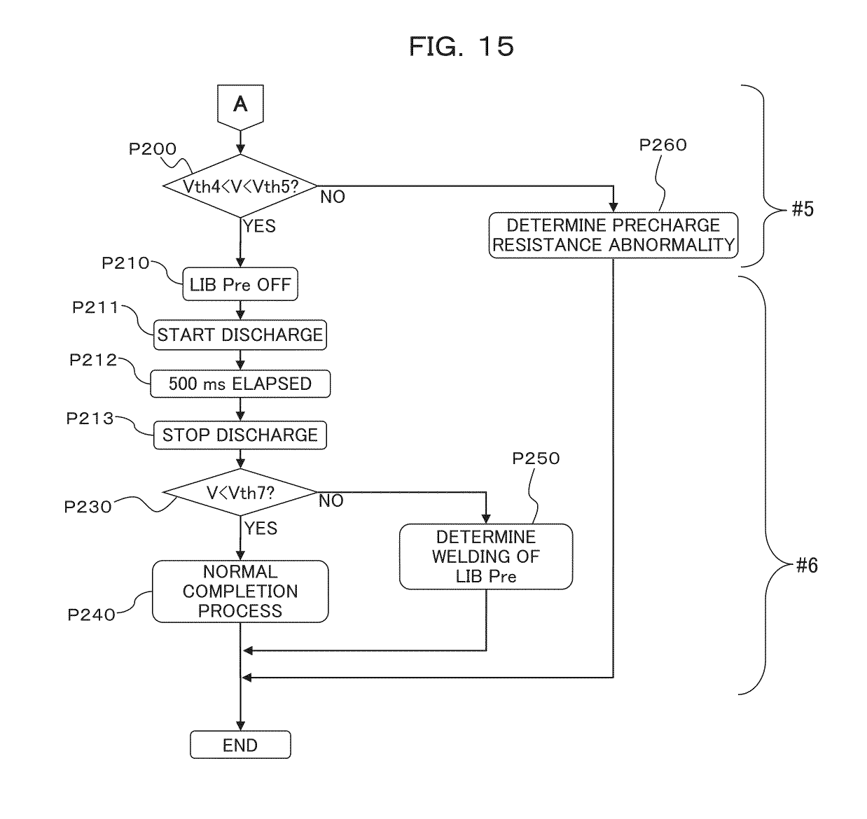

FIGS. 14 and 15 illustrate an example of the intermittent discharge operation. As can be understood by comparing FIGS. 14 and 15 and FIGS. 12 and 13 with each other, in the second embodiment, in each of Sequences #2 to #6, discharge is stopped when a predetermined time (for example, 500 ms) elapses from the start of discharge, which is different from the first embodiment.

For example, as illustrated in FIG. 14, in Sequence #2, after the negative-side main relay 82 is turned off (Process P20), discharge is started (Process P30), and, when a predetermined time elapses (Process P31), the discharge is stopped (Process P32).

Further, in Sequence #3, after the precharge relay 83 is turned on (Process P90), discharge is started (Process P91), and, when a predetermined time elapses (Process P92), the discharge is stopped (Process P93).

Furthermore, in Sequence #4, after the positive-side main relay 81 is turned off (Process P120), discharge is started (Process P121), and, when a predetermined time elapses (Process P122), the discharge is stopped (Process P123).

Further, in Sequence #5, after the positive-side main relay 81 is turned on (Process P150), discharge is started (Process P151), and, when a predetermined time elapses (Process P152), the discharge is stopped (Process P153).

Furthermore, as illustrated in FIG. 15, after the precharge relay 83 is turned off (Process P210), discharge is started (Process P211), and, when a predetermined time elapses (Process P212), the discharge is stopped (Process P213).

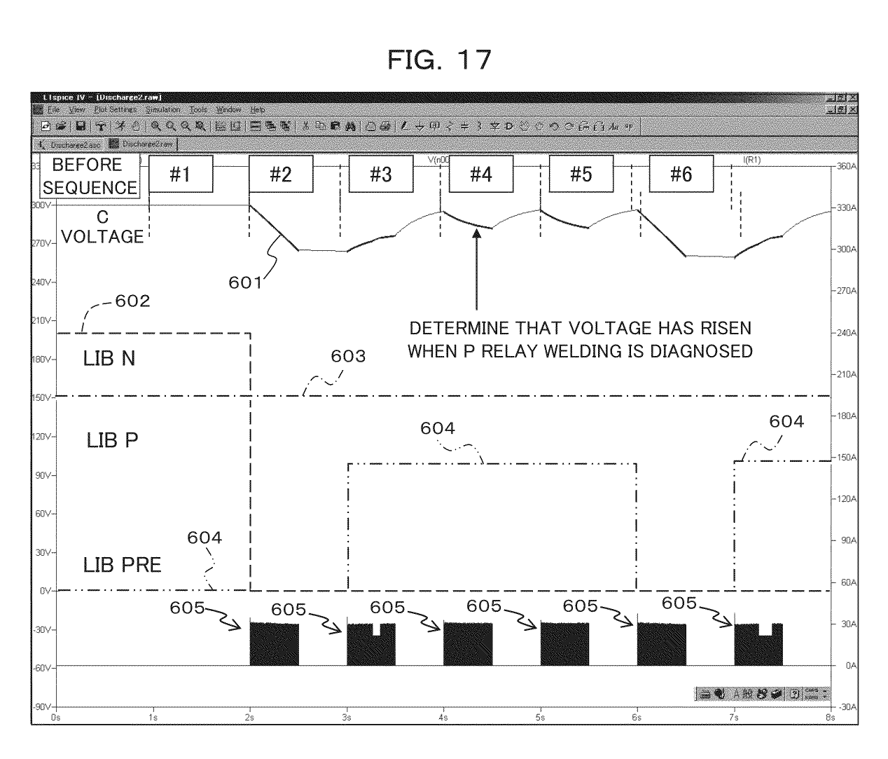

The other processes (the determination process and the like) to which the same reference numerals as those of the first embodiment (FIGS. 12 and 13) are depicted in FIGS. 14 and 15 are the same as those of the first embodiment. FIG. 16 illustrates an example of a change (see reference numeral 601) of the C voltage in a case where the above-described intermittent discharge is performed. FIG. 17 illustrates a case where the positive-side main relay 81 is determined as being welded because the C voltage is not below the predetermined voltage threshold Vth6 in Sequence #4.

As described above, during the period corresponding to Sequences #2 to #6, by intermittently performing discharge, the discharge period can be shorter than that of the first embodiment. Accordingly, the amount of the consumed current according to the discharge can be suppressed.

In the second embodiment described above, in each of the periods corresponding to Sequences #2 to #6, the start and the stop of discharge are performed, however; the start and the stop of discharge may be performed only for some of the periods.

### Third Embodiment

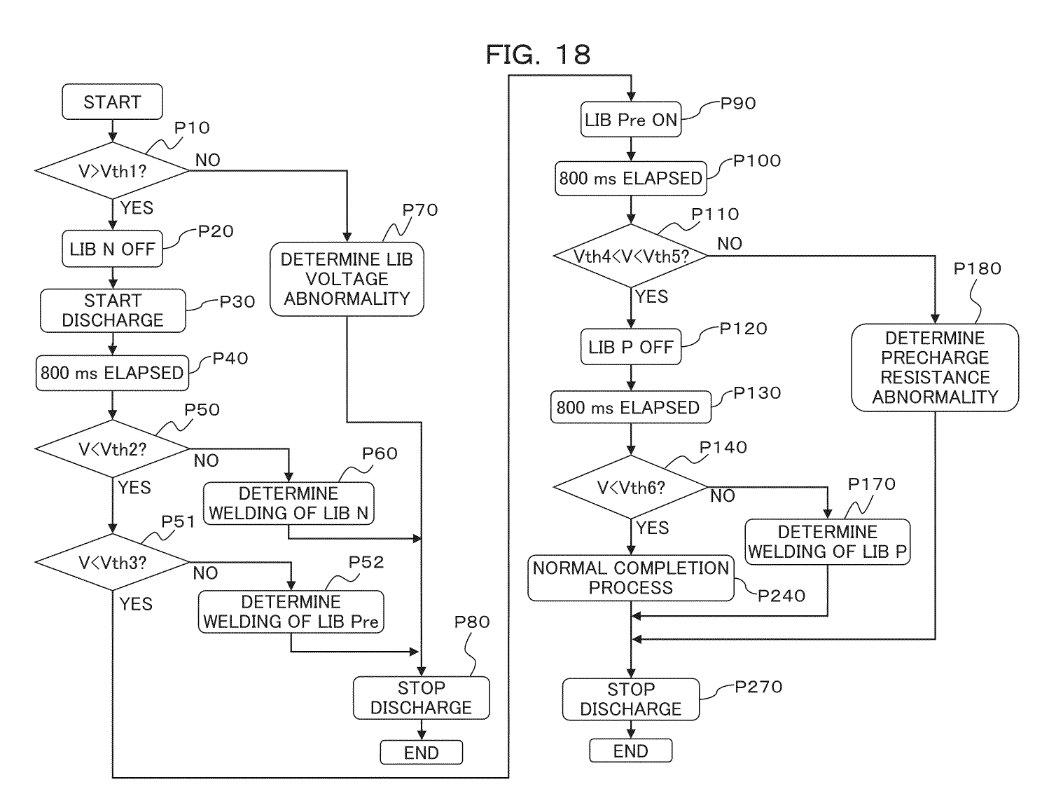

FIG. 18 illustrates an example of a flowchart of a relay welding diagnosis according to a third embodiment. The flowchart illustrated in FIG. 18 is different from the flowchart according to the first embodiment illustrated in FIGS. 12 and 13 in that Processes P51 and P52 are added. Further, in the case illustrated in FIG. 18, Processes P160, P190, P200, P210, P220, P230, and P250 illustrated in FIGS. 12 and 13 are unnecessary (deleted).

The reason for this is that, in Processes P51 and P52, in a case where the C voltage V is determined as not being below the predetermined threshold Vth3 by the determiner 102 (“No” in Process P51), it can be determined that the precharge relay 83 is welded in Process P52. In a case where the precharge relay 83 is determined as being welded, the discharge is stopped by the discharge controller 104 (Process P80).

In a case where the C voltage V<Vth3 is satisfied (“Yes” in Process P51), Process P90 and subsequent processes illustrated in FIG. 18 are performed. For example, the determination of the abnormality of the precharge resistor R1 (Processes P110 and P180) and the determination of the welding of the positive-side main relay 81 (Processes P140 and P170) are performed. Here, the voltage threshold Vth3 satisfies “Vth3<Vth2<Vth1”.

According to the third embodiment described above, the welding of the precharge relay 83 can be detected more quickly than that of each of the aforementioned embodiments.

### Fourth Embodiment

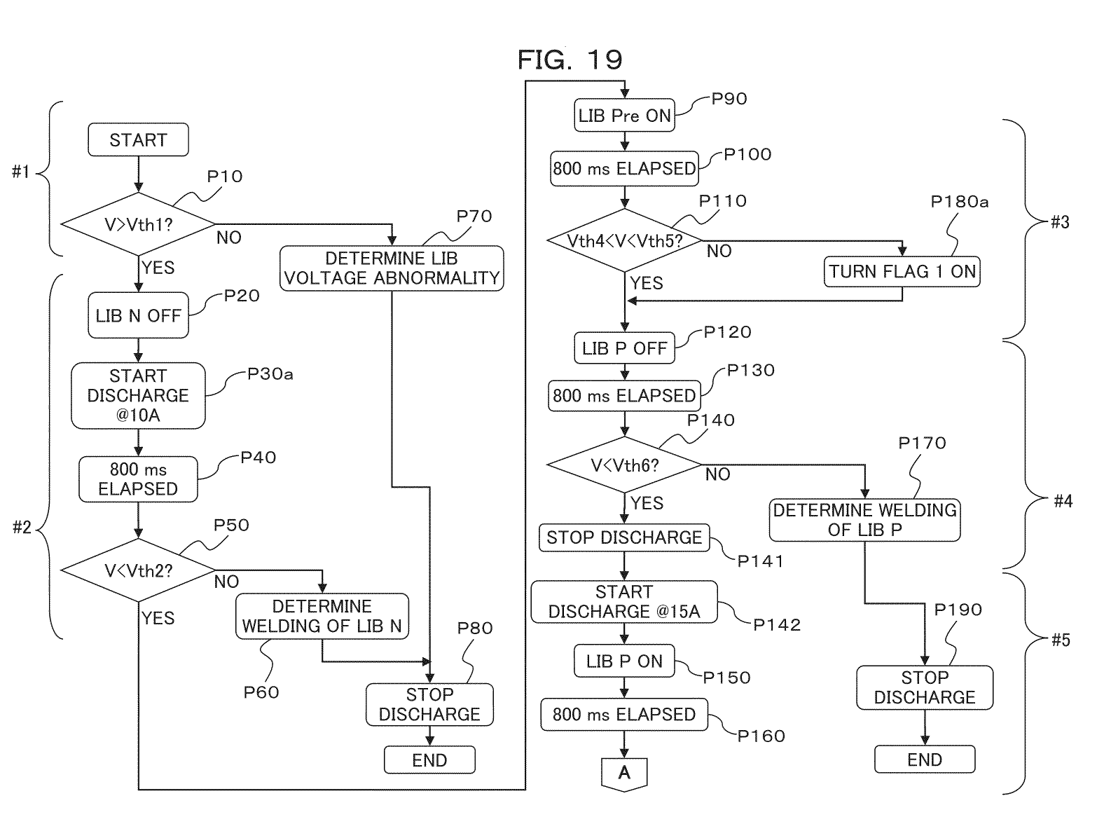

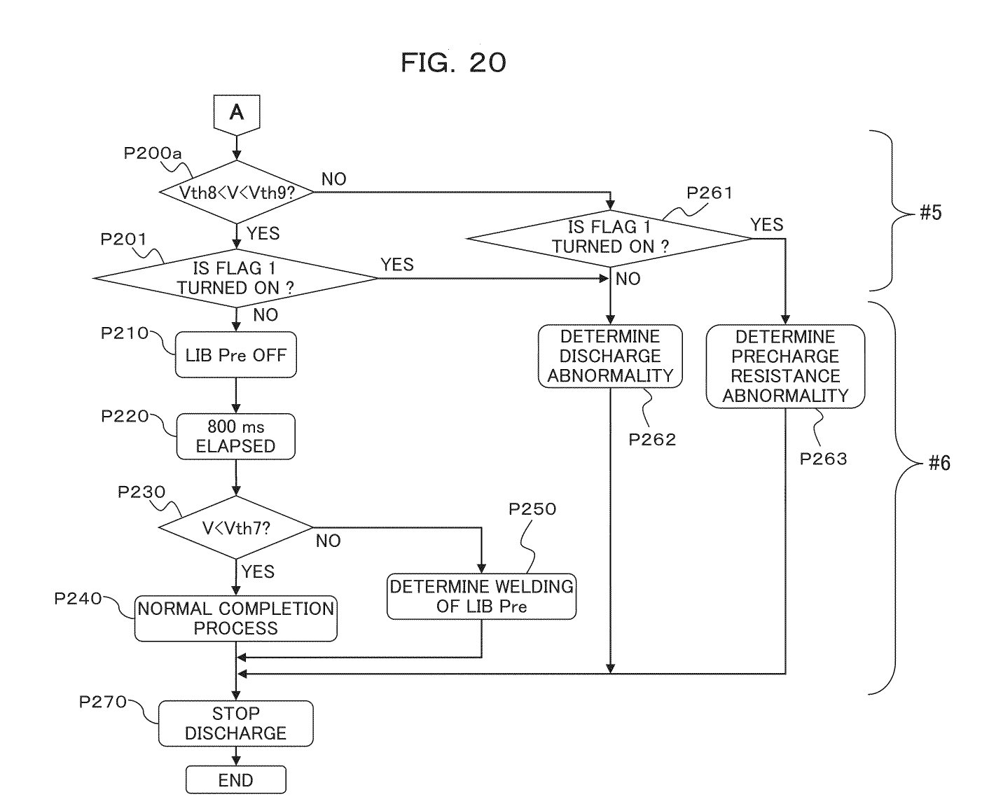

FIGS. 19 and 20 illustrate an example of the flow of a relay welding diagnosis according to a fourth embodiment. The flowchart illustrated in FIGS. 19 and 20 is different from the flowchart according to the first embodiment illustrated in FIGS. 12 and 13 in that the discharge current is controlled to different current values in Sequences #2 and #5. The control of the discharge current may be performed by the discharge controller 104.

The discharge controller 104 according to this embodiment is an example of a discharge current amount controller configured to control the amount of electric charge accumulated in the capacitor C or the electric charge supplied from the LiB 50 during the electric charge is discharged through the inverter 30 and the three-phase motor 40, for each sequence.

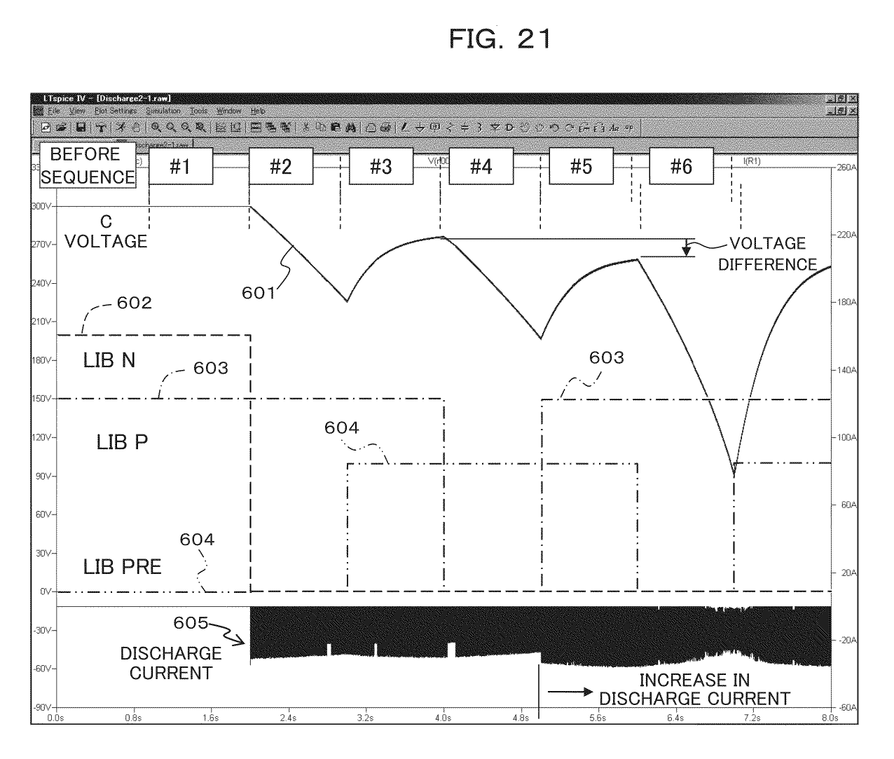

For example, in Sequence #2, after the negative-side main relay 82 is turned off (Process P20), discharge with 10 ampere (A) is started (Process P30a). On the other hand, in Sequence #5, after the C voltage V is determined as being below the voltage threshold Vth6 (“Yes” in Process P140), the discharge with 10 A is stopped (Process P141), and discharge with 15 A is started (Process P142). Accordingly, as illustrated in FIG. 21, a discharge current increases to a value higher than that of the periods corresponding to Sequences #2 to #4.

As described above, by differentiating (changing) the discharge current, as illustrated in FIG. 21, there is a difference between C voltages of periods corresponding to Sequences #3 and #5. The determiner 102 can distinctively determine an abnormality of the precharge resistor R1 and an abnormality of the discharge based on the voltage difference.

For this, in a case where the C voltage V does not satisfy “Vth4<V<Vth5” in process P110 (Sequence #3) illustrated in FIG. 19, the determiner 102 according to the fourth embodiment does not determine an abnormality of the resistor R2 in this stage but sets a “flag 1” to “On” (Process P180a). For example, “flag 1” is stored in the aforementioned memory 103.

Then, as illustrated in FIG. 20, after it is determined whether the C voltage V satisfies Vth8<V<Vth9 in the subsequent Sequence #5 (Process P200a), the determiner 102 checks whether or not the “flag 1” is set to “On” (Processes P201 and P261). Here, voltage values Vth8 and Vth9, for example, satisfy “Vth8<Vth9<Vth4<Vth5”. As a non-limited example, in a case where the battery voltage V1 is 300 V, Vth8 and Vth9 may be set to 252 V and 267 V, respectively.

In a case where the C voltage V does not satisfy “Vth8<V<Vth9”, and the “flag 1” is set to “On” (“No” in Process P200a and “Yes” in Process P261), the determiner 102 determines that there is an abnormality of the precharge resistor R1 (Process P263).

On the other hand, in a case where the C voltage V does not satisfy “Vth8<V<Vth9”, and the “flag 1” is set to “Off” (“No” in Process P200a and “No” in Process P261), the determiner 102 determines that there is an abnormality of the discharge (Process P262). Further, in a case where the C voltage V satisfies “Vth8<V<Vth9”, and the “flag 1” is set to “On” (“Yes” in Process P200a and “Yes” in Process P261), the determiner 102 determines that there is an abnormality of the discharge (Process P262).

As described above, according to the fourth embodiment, the amount of the discharge current during the discharge period is changed (differentiated). Thus, the determiner 102 can distinctively detect an abnormality of the precharge resistor R1 and an abnormality of the discharge based on a change in the C voltage between Sequences #3 and #5 in which current amounts are controlled to be mutually-different.

### Fifth Embodiment

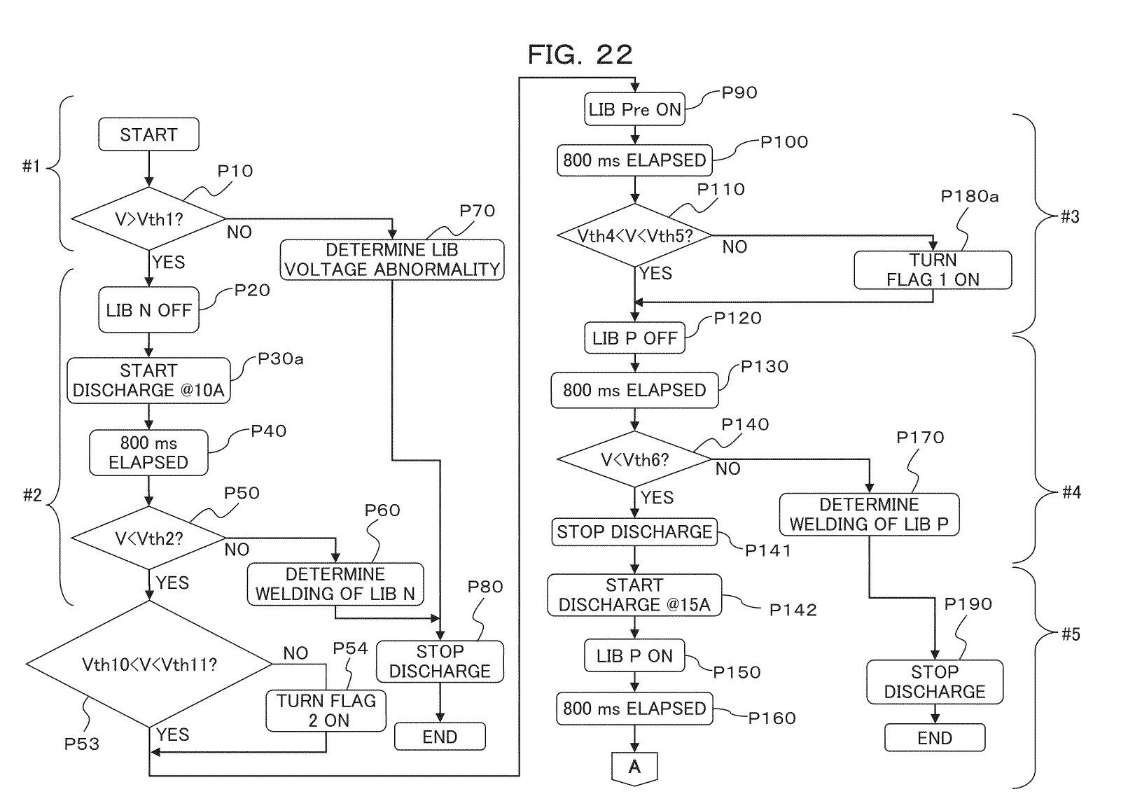

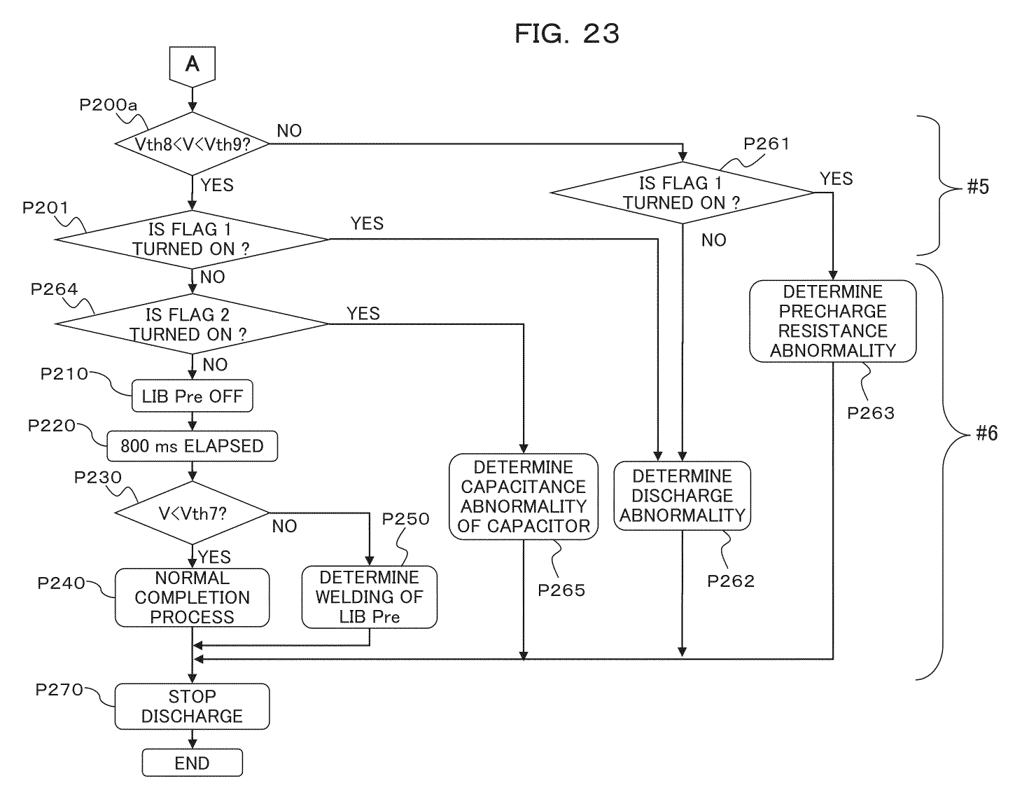

FIGS. 22 and 23 illustrate an example of the flow of a relay welding diagnosis according to a fifth embodiment. The flowchart illustrated in FIG. 22 is different from the flowchart according to the fourth embodiment illustrated in FIG. 19 in that Processes P53 and P54 are added. Further, the flowchart illustrated in FIG. 23 is different from the flowchart according to the fourth embodiment illustrated in FIG. 20 in that Processes P264 and P265 are added.

As illustrated in FIG. 22, in Process P53, in a case where the C voltage V is determined as being below the voltage threshold Vth2 (“Yes” in Process P50), the determiner 102 further determines whether the C voltage V drops to a voltage according to the resistance value R_{dis} acquired by simulating the discharge as a resistor and the capacitance value of the capacitor C. For example, the determiner 102 determines whether or not the C voltage V satisfies “Vth10<V<Vth11”. Here, voltage thresholds Vth10 and Vth11, for example, may be set based on the following Equation (2) in consideration of the capacitance of the capacitor C, the resistance value R_{dis}, and a variation in the C voltage V. As a non-limited example, in a case where the battery voltage V1 is 300 V, Vth10 and Vth11 may be set to 230 V and 250 V, respectively.

V=V1*[exp{−0.8/(C·R_{dis})}] (2)

In Equation (2), V1 represents the battery voltage of the Lib 50, and C represents the capacitance of the capacitor C.

As a result of the above-described determination, in a case where “Vth10<V<Vth11” is satisfied (the C voltage V does not drop into a predetermined voltage range during discharge) (“No” in Process P53), the determiner 102 sets a “flag 2” to “On” (Process P54). The “flag 2” is stored in, for example, the memory 103.

On the other hand, as the result of the above-described determination, in a case where “Vth10<V<Vth11” is satisfied (“Yes” in Process P53), the VCU 10, similar to the fourth embodiment, performs Process P90 and subsequent processes.

Next, as illustrated in FIG. 23, in Process P264, the determiner 102 determines whether or not the “flag 2” is set to “On”. This determination is made in a case where the “flag 1” is set to “Off” (in the case of “No” in Process P201).

As a result of the determination made in Process P264, in a case where the “flag 2” is set to “On” (in the case of “Yes”), the determiner 102 determines that there is an abnormality of the capacitor C (Process P265). On the other hand, in a case where the “flag 2” is set to “Off” (“No” in Process P264), Processes P210, P22, P230, P240, P250 and P270 described above are performed.

As described above, according to the fifth embodiment, the same advantages as those of the fourth embodiment can be achieved, and additionally, by determining whether or not the C voltage satisfies “Vth10<V<Vth11” during the discharge, a discharge abnormality and an abnormality of the capacitor C can be distinctively detected. Accordingly, an abnormality of the precharge resistor R1, an abnormality of the capacitor C, and a discharge abnormality can be detected individually.

According to the technology described above, an abnormality of the resistor of the relay circuit can be detected quickly or rapidly.

(Others)

The voltage thresholds used in each of the aforementioned embodiments may be determined in comprehensive consideration of the battery voltage V1 of the LiB 50, variations of components such as the resistor and the capacitor, a determination time, switching control of the IGBT, and the like. The voltage thresholds may be determined (set) as absolute values as described in each embodiment and may also be determined using a voltage value before the determination such as the battery voltage V1×R_{dis}/(R_{dis}+R1)±5% (variation tolerance).

Further, in each of the embodiments described above, all of the relay controller 101, the determiner 102, the memory 103, and the discharge controller 104 are provided in the VCU 10. However, for example, a part of or all of the units 101 to 104 may be provided in the MCU 20. For example, by providing the relay controller 101 and the discharge controller 104 into the MCU 20, the communication amount using the SPI communication between the VCU 10 and the MCU 20, which is made during the discharge period or at the time of controlling the amount of the discharge current, can be suppressed.

Furthermore, in each of the embodiments described above, the motor driving system 1 (the diagnosis apparatus and the diagnosis method for a relay circuit) is applied to a vehicle such as an EV or a HEV, however; the motor driving system 1 may be generally applied to other ridable machines such as a train and a ship.

All examples and conditional language provided herein are intended for pedagogical purposes to aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiment(s) of the present invention have been described in detail, it should be understood that the various changes, substitutions, and alterations could be made hereto without departing from the spirit and scope of the invention.

What is claimed is:

1. A diagnosis apparatus for a relay circuit, the relay circuit comprising:
a load circuit supplied with a direct-current (DC) voltage from a direct-current (DC) power supply;
a capacitor connected to both ends of the load circuit;
a first main relay provided for a power supply line between a positive terminal of the DC power supply and one end of the load circuit;
a second main relay provided for a power supply line between a negative terminal of the DC power supply and the other end of the load circuit;
a series circuit of a first resistor and a precharge relay that are provided in parallel with the second main relay; and
a second resistor connected to both ends of the load circuit,
the diagnosis apparatus comprising:
a voltage sensor configured to detect a both-end voltage of the capacitor;
a relay controller configured to perform an on-off control on each of the relays in accordance with a predetermined sequence; and
a determiner configured to detect an abnormality of the first resistor based on the voltage detected by the voltage sensor and an equivalent resistance value representing a discharge process in a sequence including the discharge process, the discharge process being performed by the relay controller to turn on both of the first main relay and the precharge relay and turn off the second main relay to apply a reactive current with an amount indicated by a value stored in a memory to the load circuit.

2. The diagnosis apparatus according to claim 1, wherein the determiner determines whether any one of the relays is welded based on a state change of the both-end voltage in each of sequences performed by the relay controller, the sequences comprising:
a sequence turning off the second main relay after a sequence turning on both of the main relays and turning off the precharge relay;
a sequence turning off the first main relay after turning on both of the precharge relay and the first main relay and turning off the second main relay; and
a sequence turning off the precharge relay after turning on both of the precharge relay and the first main relay and turning off the second main relay.

3. The diagnosis apparatus according to claim 1, wherein the determiner determines an abnormality of the first resistor in response to an out-of-range detection of the both-end voltage from a predetermined voltage range during the sequence performed by the relay controller to turn on both of the precharge relay and the first main relay and turn off the second main relay.

4. The diagnosis apparatus according to claim 1, further comprising a discharge period controller configured to control a period during which electric charge accumulated in the capacitor or electric charge supplied from the DC power supply is discharged through the load circuit for each sequence.

5. The diagnosis apparatus according to claim 1, further comprising a discharge current amount controller configured to control the amount of discharge of electric charge accumulated in the capacitor or electric charge supplied from the DC power supply through the load circuits for each sequence,
wherein the determiner distinguishes abnormalities of the first resistance and the discharge based on a change of the both-end voltage between sequences controlled to mutually-different discharge current amounts by the discharge current amount controller.

6. The diagnosis apparatus according to claim 5, wherein the determiner determines whether or not the both-end voltage drops to a voltage according to a resistance value numerically-modeling the discharge as a resistance and the capacitance value of the capacitor during the discharge to detect an abnormality of a capacitance value of the capacitor.

7. A method of diagnosing a relay circuit, the relay circuit comprising: a load circuit supplied with a direct-current (DC) voltage from a direct-current (DC) power supply; a capacitor connected to both ends of the load circuit; a first main relay provided for a power supply line between a positive terminal of the DC power supply and one end of the load circuit; a second main relay provided for a power supply line between a negative terminal of the DC power supply and the other end of the load circuit; a series circuit of a first resistor and a precharge relay that are provided in parallel with the second main relay; and a second resistor connected to both ends of the load circuit, the method comprising:
performing a discharge process to turn on both of the first main relay and the precharge relay and turn off the second main relay to apply a reactive current with an amount indicated by a value stored in a memory to the load circuit; and
detecting, in the discharge process, an abnormality of the first resistor based on a both-end voltage of the capacitor detected by a voltage sensor and an equivalent resistance value representing the discharge process.
